(19) United States
(12) Patent Application Publication
(10) Pub. No.: US 2006/0289034 A1
(43) Pub. Date: Dec. 28, 2006

(54) Compositions containing free radical quenchers

(76) Inventors: Robert J. Small, Tucson, AZ (US); Christopher G. Hayden, Alexandria, VA (US)

Correspondence Address: MORGAN LEWIS & BOCKIUS LLP, 1111 PENNSYLVANIA AVENUE NW, WASHINGTON, DC, 20004, US

(21) Appl. No.: 11/476,090

(22) Filed: Jun. 28, 2006

Related U.S. Application Data
(63) Continuation of application No. PCT/US04/43307, filed on Dec. 23, 2004.
(60) Provisional application No. 60/533,258, filed on Dec. 31, 2003.

(51) Int. Cl. B08B 6/00; H01L 21/461; B44C 1/22

(52) U.S. Cl. 134/1.3; 438/745; 216/83; 134/2

(57) ABSTRACT

The invention relates to a method of cleaning the surface of a substrate to remove post-etch residue or post chemical mechanical polishing residues from the surface of a substrate. Specifically, the present invention relates to a method of post-CMP or post-etch cleaning. The method involves contacting the surface of a substrate with a CMP composition or an etching composition, that contains free radicals, and subsequently contacting the surface of the substrate with a composition that comprises a free radical quencher.

### RELATED APPLICATIONS

This application is a continuation of the national stage entry of PCT/US2004/043307 filed Dec. 23, 2004, and claims priority to U.S. Provisional Application 60/533,258 filed on Dec. 31, 2003, the disclosures of which are incorporated herein for all legal purposes.

### FIELD OF THE INVENTION

The invention relates to a method of cleaning the surface of a substrate to remove residues from the surface of a substrate. Specifically, the methods are useful for removing residues that remain on the surface of a substrate after the substrate has been etched or has undergone chemical mechanical polishing (“CMP”).

### BACKGROUND OF THE INVENTION

Substrates, such as integrated circuits, consist of a plurality of active layers, in many cases millions of layers, sequential deposited on a base, such as silicon or gallium arsenide base. The conductive layers are typically separated from each other with a layer of silicon-based dielectric materials. The active layers are interconnected to form functional circuits and components. Generally, each active layer comprises a plurality of metals, metallic compounds, and/or dielectric materials (for example, aluminum, tungsten, and various alloys thereof are extensively used as metals).

Typically, the active layers are patterned by masking and etching processes that form a pattern of structures in the surface of a dielectric material. After the masking and etching processes, the surface of the dielectric material is cleaned in a post etch cleaning step to remove any residue left on the layer. After cleaning, a metal-containing material is deposited on the surface of the etched dielectric material layer to fill the structures on the dielectric material with the metal and to coat the dielectric material with the metal. The metal coated layer is then polished to provide a smooth layer of dielectric material with a pattern of metal containing material embedded in the dielectric material. Typically, the polishing process is performed using a chemical mechanical polishing step. After the polishing step, the surface of the dielectric layer is again cleaned to remove any residue left on the layer in a post chemical mechanical polish cleaning step. The substrate is now ready for the next step of the process that involves providing another layer of dielectric material which can also undergoes the masking, etching, and deposition processes and the post etch cleaning and post chemical mechanical polish cleaning steps.

In a typical etching process, a mask (generally comprising polymeric material) is created on the surface of the layer to shield various parts of the surface of the layer to provide a pattern on the surface of the layer. The surface of the layer is then contacted with an etching composition is to etch away the parts of the surface that are not protected by the mask. The etching composition may be a fluid or a gas (e.g., a plasma). After the etching process, a residue remains on the surface of the layer. The residue remaining after etching includes metallic material, metal compounds (especially compounds formed from the metal on the substrates, and reactive materials in the etching composition, such as, fluorides, oxides, phosphates, and the like), and also various organometallic materials. The residue must be removed from the surface of the substrate. This residue and the polymeric masking material may be partially removed by ashing, which removes some residue but tends to increase the chemical resistance of residues not removed. The residues, which may or may not be a residue that can be removed by ashing, must be removed without corroding the surface of the layer. Accordingly, a cleaner for removing the residue must be reactive with the desired residue but must not attack the surface of the layer, which, as noted above, may contain dielectric materials, metals, and metal compounds. Generally, oxidizers are used in post-etch cleaners. Some oxidizers used in post-etch cleaning, however, form free radicals, which are non-selective in the material they attack and accordingly, can attack the surface of the layer. The amount of free radicals formed is dependent on the composition of the cleaner. Some cleaner compositions being substantially more prone to free radical generation then others. The non-selectivity of these powerful free radicals is undesirable for post etch cleaning. Additionally, it is believed that free radical-induced corrosion of a layer leaves the corroded layer more susceptible to corrosion by the oxidizers present in the cleaner composition.

In a typical chemical mechanical polishing step, the surface of the substrate is placed in direct contact with a rotating polishing pad at a controlled downward pressure. A chemically reactive solution, commonly referred to as a “slurry,” is present between the pad and the surface of the substrate to be polished. Polishing of the surface results from the combined effects of the slurry chemically reacting with the surface of the substrate and the rotational movement of the pad relative to the surface of the substrate. Polishing is continued in this manner until the surface of the substrate is removed to a desired thickness. The composition of the chemical mechanical polishing composition is an important factor in determining the rate at which metal film layers are removed by chemical-mechanical polishing. If the chemical agents in the chemical mechanical polishing composition are selected properly, the chemical mechanical polishing composition can be tailored to provide effective polishing of a layer at desired polishing rates while minimizing the formation or creation of surface imperfections or defects. In some circumstances, the chemical mechanical polishing composition can preferably provide controlled polishing selectivity for one or more thin film materials relative to other thin-film materials.

After chemical mechanical polishing, the surface of the layer remains covered with a residue that contains the chemical mechanical polishing composition, and materials removed during polishing. Active ingredients of the chemical mechanical polishing composition that remain on the surface of the layer, include for example, oxidizers and abrasives. Of particular concern are metals that plates onto, absorbs onto, or are in some way become bound to the surface of the layer. These metals can be present in the chemical mechanical polishing composition or can be formed from the action of polishing a surface that includes a metal. For further processing of the substrate after chemical mechanical polishing, it is typically necessary to remove the residue. Residue removal requires a specialized post chemical mechanical polish cleaning step. This step needs to effectively remove any residue on the surface of the layer.

It is essential that during the etching steps post-etch cleaning steps, chemical mechanical polishing steps, and post chemical mechanical polishing steps that the degree of corrosion of each material in the layer is strictly controlled; that all contaminants are substantially removed from the surface of the layer; and that each step is performed at a commercially acceptable speed. The post etch cleaner compositions, chemical mechanical polishing compositions, and post chemical mechanical polish cleaning compositions typically contain oxidizers, preferably, oxidizers that have a strong tendency to oxidize materials that the manufacturer wants removed from the surface of the substrate, but little or no tendency to oxidize materials that the manufacture does not want removed. The requirement of commercially acceptable speed, however, necessitates aggressive oxidizers. A typical by-product of many commercially used aggressive oxidizers is free radicals. Free radicals, especially, but not exclusively, hydroxyl free radicals, superoxide free radicals, and the like, however, can be problematic because, due to their relatively reactive nature, attack the surface of virtually any layer, leading ultimately to corrosion of the bulk of the layer.

Selected metal ions, in particular copper, but also other materials that contain, for example, iron, can interact with selected oxidizers in the chemical mechanical polishing composition to facilitate the formation of free radicals. These metals may be in the original chemical mechanical polishing composition or may become part of the chemical mechanical polishing composition as a result of polishing a surface that contains a metal.

Copper is a new and preferred electrically conductive material used in fabricating integrated circuits because it has superior electromigration resistance and lower resistivity than many other electrically conductive materials such as aluminum. The use of copper in integrated circuits, however, presents some difficult challenges since copper readily diffuses into conventional silicon-based dielectric materials such as polysilicon, single-crystalline silicon, silicon dioxide, low-k inorganic and organic materials, and the like. Once the silicon-based dielectric material has been contaminated with copper atoms, the dielectric constant of the silicon-based dielectric material is adversely affected. Accordingly, a barrier layer or liner film must be applied to the silicon-based dielectric material in order to prevent copper diffusion These barrier layers typically comprise metals (including, for example, alloys) or metal compounds (including, for example, nitrides), wherein the metal forming the barrier layer can be Ta, Ti, W, and the like. Post etch cleaning, chemical mechanical polishing, and post chemical mechanical polish cleaning of copper containing substrates is further complicated because there are more materials on the substrate surface, i.e., the materials in the barrier layer, and because copper can, in some circumstances, accelerates the formation of free radicals which, as noted above, can be problematic.

It is well known in the art that benzotriazole (BTA) can be added to chemical mechanical polishing compositions to protect copper from corrosion. U.S. Pat. No. 5,770,095 to Sasaki et al., alleges that copper reacts with BTA to form a secure film comprising a copper chelate compound or complex. This film serves as a protective barrier on the copper to prevent oxidization or corrosion of the underlying copper by the chemical agents in the chemical mechanical polishing composition.

Generally, modern chemical mechanical polishing compositions attempt to provide the fastest possible rate of polishing while maintaining control over the process. The fastest rate, however, is achieved using high concentrations of one or more oxidizers that inadvertently cause free radical formation. Accordingly, the aggressive chemical action of these chemical mechanical polishing compositions disadvantageously tends to corrode metals, e.g., the copper lines of a copper damascene structure, during polishing. Other methods of chemical mechanical polishing use chemical mechanical polishing compositions containing a combination of oxidizers to promote a catalytic effect. In these compositions a weaker oxidizer with an affinity for the material to be oxidized is regenerated by a stronger oxidizer, typically present in a concentration greater than the weaker oxidizer, but with a lower affinity for the material to be oxidized. One inadvertent result of such combinations, however, can be the formation of free radicals. Another approach to chemical mechanical polishing has been to utilize chemical mechanical polishing composition that are designed to encourage formation of free radicals to provide a fast polishing rate.

Recently developed chemical mechanical polishing composition have attempted to solve the problem of excessive copper corrosion during chemical mechanical polishing. For example, U.S. Pat. No. 6,508,953 to Li et al. and its divisional application Published U.S. Patent Application No. 2003/0098434 discloses a chemical mechanical polishing composition, comprising an oxidizing agent which releases free radicals, and a non-chelating free radical quencher that effectively retards copper corrosion by quenching the free radicals prior to interaction with a copper containing surface. Oxidizing agents that release free radicals according to U.S. Pat. No. 6,508,953 include peroxides, peroxydiphosphates, persulfates and combinations thereof. Ascorbic acid, thiamine, 2-propanol, and alkyl glycol are preferred free radical quenchers with ascorbic acid being the most preferred.

Systems that add free radical quenchers to a chemical mechanical polishing composition, such as those disclosed in U.S. Pat. No. 6,508,953 are, of course, not applicable for chemical mechanical polishing compositions that are designed to encourage free radical formation, since the free radical quencher present in the composition would quench any free radicals.

It appears that polishing is greatly enhanced by the generation of free radicals. This advantage of enhanced polishing would be lost if free radical quenchers were incorporated into chemical mechanical polishing compositions. However, free radicals can be problematic if they are not removed since they can corrode the surface of the substrate being polished.

Commonly assigned U.S. application Ser. No. 10/074,757, filed Feb. 11, 2002, and U.S. application Ser. No. 10/361,822, filed Feb. 11, 2003, the disclosures of which are expressly incorporated herein, disclose chemical mechanical polishing compositions that contained particles specifically designed and coated with, for example, ions of iron, copper, or silver that rapidly and efficiently react with selected oxidizers to create free radicals. The disclosed compositions have greatly increased rates of residue removal compared to other chemical mechanical polishing compositions, while maintaining controllable polishing parameters, while using low concentrations of commonly used oxidizers, and without adding metal contamination to the surface of the layer being polished.

A need exists in chemical mechanical polishing processes to reduce or remove undesired residues caused by free radical induced corrosion/erosion. Specifically, a need exists for an improved post chemical mechanical polish cleaning method to minimize undesired corrosion due to free radical formation in the chemical mechanical polishing composition and the post chemical mechanical polish cleaning composition. A further need exists for an improved method to remove post-etch residues and to minimize undesired free radical induced corrosion during the post-etch residue cleaning process.

### SUMMARY OF THE INVENTION

A method of chemical mechanical polishing of a substrate comprising:

A) providing a substrate comprising a surface;

B) polishing the surface of the substrate with a chemical-mechanical-polishing composition comprising
(i) an oxidizer; and
(ii) a diluent,
   wherein the chemical-mechanical-polishing composition contains free radicals; and

C) adding a free radical quencher to the chemical mechanical polishing composition just prior to completing polishing of the surface of the substrate with the chemical mechanical polishing composition, wherein the free radical quencher is added in an amount sufficient to reduce corrosion of the surface of the substrate to less than 50% of the amount of corrosion that would occur in the absence of the of the free radical quencher.

Another aspect of the invention is directed to a method of cleaning the surface of a substrate after chemical mechanical polishing cleaning. The method comprises the steps of:

A) providing a substrate comprising a surface that had been polished with a chemical mechanical polishing composition;

B) contacting the surface with a post chemical mechanical-polish cleaning composition comprising:
(i) a diluent; and
(ii) a free radical quencher in an amount sufficient to reduce corrosion of the surface of the substrate to less than 50% of the amount of corrosion that would occur in the absence of the of the free radical quencher.

Another aspect of the invention is further directed to a method of chemical mechanical polishing of a substrate. The method comprises the steps of:

A) providing a substrate comprising a surface;

B) polishing the surface of the substrate with a chemical-mechanical-polishing composition comprising:
(i) an oxidizer, and
(ii) a diluent,
   wherein the chemical-mechanical-polishing composition contains free radicals; and

C) adding a free radical quencher to the chemical mechanical polishing composition just prior to completing polishing of the surface of the substrate with the chemical mechanical polishing composition, wherein the free radical quencher is added in an amount sufficient to reduce corrosion of the surface of the substrate to less than 50% of the amount of corrosion that would occur in the absence of the of the free radical quencher.

Another aspect of the invention further relates to a method of cleaning the surface of a substrate after etching the surface of the substrate comprising:

A) providing a substrate comprising a surface that has been etched with an etching composition,

B) contacting the etched substrate surface with a post-etch cleaner composition comprising:
(i) an oxidizer,
(ii) a diluent, and
(iii) a free radical quencher in an amount sufficient to reduce corrosion of the surface of the substrate to less than 50% of the amount of corrosion that would occur in the absence of the of the free radical quencher in any of the above aspects, the free radical quencher may comprise ascorbic acid, thiamine, 2-propanol, solid cerium oxide particles having an average diameter ranging from about 2 nm to about 25 nm, tin ions or tin-containing compounds, a silicate, an iodide compound, a carbonate compound, one or more glycols, aromatic alcohols, C₁-C₄ alkyl glycols, resorcinol, a C₂ to C₄ alkyl hydroxy phenol such as 3,5-di-tert-butyl-4-hydroxytoluene, tert-butyl-4-hydroxyanisole, hydroquinone, retinoic acid, D-alpha-tocopherol, or combination thereof. The free radical quncher may comprise a ketone. These various quenchers are not equivalent, but it is within the skill of one of normal skill in the art, having benefit of this disclosure, to select useful quenchers in useful amounts depending on the materials contacting the substrate and generating the free radicals.

### DETAILED DESCRIPTION OF THE INVENTION

The present invention is directed to (i) a method of chemical mechanical polishing, (ii) a method of post chemical mechanical polish cleaning, and (iii) a method of post-etch cleaning that protects the surface of a substrate being polished from corrosion.

In one embodiment, corrosion of the surface of a substrate during polishing is suppressed by incorporating one or more free radical quenchers into a post chemical mechanical polishing cleaner that contacts the polished surface of the substrate after the surface has been polished.

In another embodiment, corrosion of the surface of a substrate during polishing is suppressed by incorporating one or more free radical quenchers into a chemical mechanical polishing composition at the end of the polishing process.

In another embodiment, corrosion of the surface of a substrate after etching is effectively suppressed by incorporating one or more free radical quenchers into a post etch cleaner that contacts the surface after etching.

In each embodiment listed herein, unless otherwise explicitly stated, the listing of a class of compounds, for example “a free radical quencher,” should be construed to mean one or more of that class of compounds, e.g., one or more free radical quenchers.

As used herein all concentrations expressed in percent are in weight percent based on the total weight of a composition, unless otherwise specified. The expression of an amount, for example “about 1 to about 5% of a radical releasing agent”, should be construed to mean not only any concentration between about 1% and about 5%, but also to include the endpoints of “about 1%” and “about 5%” by weight of the total composition.

4.1. Methods of chemical mechanical polishing using a post-chemical-mechanical-polish cleaning composition containing a free radical quencher: In the first embodiment of the invention, one or more free radical quenchers is incorporated into a post chemical mechanical polish cleaning composition that contacts the polished surface of the substrate after the surface has been polished with a chemical mechanical polishing composition.

The method comprises the steps of:

A) providing a substrate comprising a surface that had been polished with a chemical mechanical polishing composition;

B) contacting the surface with a post chemical mechanical-polish cleaning composition comprising:
(i) a diluent; and
(ii) a free radical quencher in an amount sufficient to reduce corrosion of the surface of the substrate to less than 50% of the amount of corrosion that would occur in the absence of the of the free radical quencher.

The term “corrosion,” as used herein, refers to the phenomenon wherein pits or depressions, usually irregular-shaped, are chemically etched on the surface of a substrate. In any method where a quantitative measure of corrosion is specified, the preferred method of evaluating corrosion is with an atomic force microscope, where the degree of corrosion is proportional to roughness, e.g., a roughness of 20 angstroms when no quenchers are used in the post-CMP cleaners versus a roughness of 10 or less when quenchers are present in the post CMP cleaners. Alternately, but less preferably, the change in corrosion can be evaluated with tools designed for such, for example the AIT XP™ instrument available from KLA-Tencor Inc. In another embodiment, the method further comprises removing the post chemical mechanical polish cleaner composition from the substrate.

In another embodiment, the post chemical mechanical polishing composition further comprises an oxidizer.

Chemical mechanical polishing typically involves contacting the surface of a substrate with a solution comprising an oxidizer and an abrasive while the surface of the substrate is contacted with a rotating polishing pad. After polishing, a residue remains on the surface of the substrate. Often, especially in the case of surfaces comprising copper, the residue leads to corrosion of the surface of the substrate.

Without wishing to be bound by theory, it is believed that corrosion of the surface of the substrate is caused by free radicals present in the residue when the surface is not being polished with the rotating pads. Corrosion of the surface is not a problem while the surface is in contact with the rotating pads since the rotating pads and the abrasive present in the chemical mechanical polishing composition continually smooth the corroded surface of the substrate. Indeed, the presence of free radicals in the chemical mechanical polishing composition can improve the rate of polishing.

Any chemical mechanical polishing composition known to those skilled in the art can be used in the methods of the invention. Representative chemical mechanical polishing compositions useful in the method of the invention include in particular: periodic acid-based chemistries, peroxide-based chemistries (including peroxide-urea, hydrohydrogen peroxide, peracetic acid, and the like), certain persulfate chemistries (particularly persulfuric acid), and hydroxylamine chemistries.

Suitable diluents, for use in the post chemical mechanical polishing cleaner composition include, but are not limited to water, low molecular weight (C₁-C₄) alcohols, and mixtures thereof, which may optionally include minor amounts (typically less than about 5% by weight) of oxidizers and/or acids. In one embodiment, the diluent is water, preferably deionized water or better.

The term quencher, as used herein, means a material that: 1) readily reacts with a component of a composition that causes corrosion on the surface of a substrate, and 2) after reacting with the component of the composition, the quencher forms a product that does not react with water to create a second component that causes more or the same amount of corrosion on the surface of the substrate as the component and the product itself causes less corrosion on the surface of the substrate so that corrosion of the surface of the substrate is substantially reduced.

In a preferred embodiment, the quencher is a material that reacts with a free radical, hereinafter refereed to as a free radical quencher. Representative free radicals include, but are not limited to, NO., O., HO., HOO., HSO₄., and the like.

The term “substantially reduced,” as used herein means that the amount of corrosion (roughness in Angstroms) of the surface of a substrate is reduced by an amount that is at least 50% less than, preferably at least 25% less than, and more preferably at least 10% less than, the amount of corrosion that would occur in the absence of the quencher.

The free radical quencher used in the post chemical mechanical polish cleaner composition of the invention can be an organic or an inorganic free radical quencher and can be a chelating free radical quencher or a non-chelating free radical quencher.

The term “non-chelating free radical quencher,” as used herein means a compound that does not readily chelate or otherwise complex with copper, but that reacts with free radicals.

The term “chelating free radical quencher,” as used herein means a chelator compound that reacts with free radical species.

The term “chelator compound,” as used herein is a compound that has multiple (i.e., at least two) polar functional groups present on the molecule in sufficient proximity to allow the molecule to bind to or chelate an ion (e.g., a metal ion or a metal-containing ion and, in particular, copper). Chelator compounds are well known to those skilled in the art. The ability of the chelator to bind an ion and the strength of the interaction between the chelator and the ion is dependent on properties of the chelator including, but not limited to, proximity of the polar functional groups on the chelator, polarity, polarizability, electrophilicity, and acidity/basicity of the chelator compound and on the properties of the ion including, but not limited to, the size of the ion (e.g., atomic radius, radius of gyration, etc.), chemical nature (e.g., atomic structure), and valence of the ion. The diluent/solvent in which the chelator compound and the ion are dispersed/dissolved, as well as other compounds/solutes dispersed/dissolved in the diluent/solvent, can also effect the ability of the chelator compound to bind an ion and the strength of the interaction between the chelator and the ion.

Typically, the distance between the polar functional groups on the chelator compound can be no further apart than about four atomic bond lengths. In one embodiment, the distance between the polar functional groups on the chelator compound are no further apart than about, three atomic bond lengths. Thus, the polar functional groups are typically less than about 7 Å from each other. In one embodiment, the polar functional groups are less than about 5 Å from each other. In one embodiment, the polar functional groups are less than about 4 Å from each other. In one embodiment, the polar functional groups are less than about 3 Å from each other. Suitable polar functional groups on the chelator compound s include, but are not limited to, hydroxyl groups, carboxylic acid or carboxylate groups, amine groups, amide groups, imine groups, imide groups, mercaptan groups, sulfonic acid or sulfonate groups, hydroxamic acid or hydroxamate groups, inorganic groups (e.g., ammonium salts), and combinations thereof. In some instances, the polar functional groups can alternately or additionally include carbonyl groups, ester groups, ether groups, urea groups, cyano groups, nitro groups, phosphonic acid or phosphonate groups, carbonate groups, and the like.

The multiple polar functional groups present on the chelator compound can be of the same type. For example, the chelator compounds oxalic acid and EDTA contain two and four —COOH groups, respectively; the chelator compound catechol contains two —OH groups; and the chelator ethylenediamine contains two —NH₂ groups. The multiple polar functional groups present on the chelator compound can also be of different types. For example, the chelator compound lactic acid contains one —OH group and one —COOH group, amino acid chelators typically contain one —NH₂ group and one —COOH group, the chelator compound citric acid contains one —OH group and three —COOH groups, the chelator compound gallic acid contains three —OH groups and one —COOH group, the chelator compound tartaric acid contains two —OH groups and two —COOH groups, and the chelator compound benzotriazole contains one amine group and two imine groups proximal to each other.

Without wishing to be bound by theory, it is believed that chelating compounds used in the methods of the invention reduce free radicals in two ways—(i) by reacting with the free radicals, and (ii) by sequestering metal ions, e.g., copper, iron, silver ions, that can, in certain circumstances, promote formation of free radicals when they are not complexed. However, it is important to realize that certain chelating compounds, are ineffective since the resulting chelating compound-metal ion complex itself can promote free radicals. Specifically, some chelator compounds when complexed with copper or iron promote free radical generation. For example, the chelating compound glycine when complexed with copper appears to promote free radical formation. Accordingly, glycine is not a suitable free radical quencher nor chelator compound when copper is present. For this reason, in some embodiments the compositions of the present invention are substantially free of chelators.

Generally, a relatively active chelator compound (such as an ionic compound) by itself is typically unstable and, at most, usually only moderately effective as a free radical quencher. However, since a relatively active chelator compound can also sequesters metal ions, it can be an important component of the post chemical mechanical polishing cleaning composition.

Representative chelating free radical quenchers useful as free-radical quenchers in the methods of the invention include but are not limited to, EDTA, DPTA, aromatic diazines (e.g., azobenzene compounds such as benzotriazole and derivatives thereof), organic dicarboxylic acids, and organic tricarboxylic acids. Other chelating-free-radical quenchers useful in the methods of the invention are humic acids (e.g., tannins acids, lignins acids, fulvic acids), and naphyltriazole.

Chelating free radical quenchers can economically be added in greater quantities than are typically used for non-chelating free radical quenchers. Chelating free radical quenchers, when used, can be used in amounts greater than 2% and in many cases greater than 4% by weight.

In some embodiments, the post chemical mechanical polish cleaning compositions used in the methods of the invention are substantially free of, or even totally free of, chelating free radical quenchers, as these organic molecules can make metal recovery from waste streams more difficult.

As used herein, unless otherwise defined, a composition characterized by the phrase “substantially free of,” in reference to a component of that composition, refers to the composition having less than about 1%, preferably less than about 0.5%, for example less than about 0.1%, or less than about 0.01% by weight. In some cases, a composition that is “substantially free of” a component can be completely free of any added component, and preferably completely free of any of that component at all.

In another embodiment, the post chemical mechanical polish cleaning compositions used in the methods of the invention comprise a chelating free radical quencher and more or more other free radical quenchers.

In one embodiment, the free radical quencher is a dissolved transition metal ion that does not interact with the oxidizer, if present, to create free radicals. The preferred example is a tin compound—tin salts and tin compounds such as tin hydrides and organo-tin compounds. Other potentially useful ions such as antimony and manganese are not preferred. Further, iron, copper, and silver ions are expressly not within this category, since these metal ions generally increase formation of free radicals. Metal-containing compounds are preferable to metal ions due to substrate contamination concerns. While larger amounts of free radical quenchers result in increased protection, other factors associated with transition metal ions including, but not limited to, cost, environmental and health concerns, as well as possible substrate contamination, discourage the use of metal ions and/or mandate low concentrations of metal ions. A small amount of tin, for example between 0.5 ppm and 500 ppm, and even as low as between 1 ppm and 40 ppm, can substantially quench free radicals in a composition.

In some embodiments, the compositions of the present invention are substantially free of, or even totally free of, a metal ion free radical quenchers, as these ions can contaminate a substrate and can create health-safety issues. If used, metal ion free radical quenchers are advantageously used with one or more other classes of free radical quenchers.

In another embodiment, the free radical quencher is a solid cerium compound, particularly a cerium oxide in the form of small particles. We have surprisingly found that small particles of cerium oxides function as free radical quenchers. In particular, very small cerium oxides particles comprising Ce₂O₃ or a mixture of Ce₂O₃ and CeO₂ are free radical quenchers. Without wishing to be bound by theory, it is believed that the transition of solid Ce₂O₃ to CeO₂ allows the material to neutralize free radicals. The free radical quenching activity, however, is significant only when the particles comprising the cerium oxides are very small. Typically the average diameter of the particles comprising cerium oxides are less than about 30 nm. In one embodiment, the particles comprising cerium oxides have an average diameter ranging from about 10 nm and about 25 nm. In another embodiment, the particles comprising cerium oxides have an average diameter such that only a few molecules of cerium oxides are involved, e.g., an average diameter ranging from about 2 nm to about 10 nm. In another embodiment, the particles comprising cerium oxides have an average diameter ranging from about 4 nm to about 7 nm. Cerium oxide free radical quenchers are relatively stable and typically easily regenerable. Amounts ranging from about 0.5 micromoles/liter to about 10 millimoles/liter of cerium are generally sufficient to substantially quench free radicals in a composition. In one embodiment, the concentration of cerium ranges from about 4 micromoles/liter to about 5 millimoles/liter.

In some embodiments, the compositions used in the methods of the invention are substantially free of, or even totally free of, solid-cerium-containing free radical quenchers, as these solids can, under certain circumstances, adhere to or be trapped on the surface of a substrate. If used these cerium-containing-solid free radical quenchers are advantageously used with one or more other classes of free radical quenchers.

In another embodiment, the free radical quenchers are inorganic acids. Examples of inorganic acids useful in the methods of the invention include, but are not limited to, phosphoric acid, phosphorus acid, sulfuric acid, sulfurous acid, and salts thereof. In one embodiment, the free radical quencher is phosphorous acid or a salt thereof. In another embodiment, the free radical quencher is phosphoric acid or a salt thereof. In another embodiment, the free radical quencher is sulfuric acid or a salt thereof. In another embodiment, the free radical quencher is sulfurous acid or a salt thereof.

In some embodiments, the post chemical mechanical polishing cleaning compositions are substantially free of, or even totally free of, inorganic acid free radical quenchers, as these acids, under certain conditions, can create precipitation problems. Typically, however, at least one inorganic acid based free radical quencher can be used. The amount of the inorganic acid free radical quencher typically ranges from about 0.001% to about 5%., These acids may unfavorably react with some substrates, accordingly, it is usually preferred to use less than about 0.5% by weight. If used these inorganic-acid-based free radical quenchers are advantageously used with one or more other classes of free radical quenchers.

In another embodiment, the free radical quencher is a silicate compound. We have surprisingly found that very small particles of silicates can function as free radical quenchers. An amount ranging from about 0.001% to about 1% is generally sufficient. In one embodiment, the amount of silicate ranges from about 0.1% to about 0.3% by weight.

In some embodiments, the post chemical mechanical polishing cleaning compositions are substantially free of, or even totally free of, silicate free radical quenchers, as these compounds can, under some circumstances, plate onto selected substrates. If used these silicate free radical quenchers are advantageously used with one or more other classes of free radical quenchers.

In another embodiment, the free radical quenchers are iodide compounds. Examples of iodide compounds useful in the methods of the invention include, but are not limited to, hydrogen iodide and ammonium iodide. These compounds, however, are only stable enough for use with point-of-use mixing. Moreover, iodide compounds can form reaction products that are difficult to deal with. Accordingly, in some embodiments iodide compounds are not used. If iodide compounds are used as a free radical quencher, it is preferred to use at most about 0.5% of the iodide compound. If iodide compounds are used as free radical quenchers they are advantageously used with one or more other classes of free radical quenchers.

In another embodiment, the free radical quencher is a carbonate compound. Carbonate compounds are generally not stable in acidic conditions, and, accordingly, are best used in compositions where the pH is at least about 5, preferably at least about 6. Generally, it is difficult to keep more than about 1% by weight of carbonate in solution, and heat further reduces solubility. It is preferred to use less than about 0.5% of carbonate compounds.

In some embodiments, the compositions of the present invention are substantially free of, or even totally free of, carbonate-based free radical quenchers, as these inorganic molecules can be unstable and can create gas pockets. If used as a free radical quencher, carbonate compounds are advantageously used with one or more other classes of free radical quenchers.

In another embodiment, the free radical quencher is a telechelic dihydroxy compounds. Representative telechelic dihydroxy compounds useful in the methods of the invention include, but are not limited to, glycerine and glycol compounds. Alkyl glycols are the preferred telechelic dihydroxy free radical quenchers, as they are inexpensive, readily removable from the surface of most substrates, and are freely soluble in most diluents used in the methods of the invention. As little as 0.05% of glycols can be used, though a more preferred concentration is between 0.1% to 1%. Glycols are typically inexpensive, and therefore can economically be added in large quantities, e.g., greater than 1%, and even greater than 4% by weight. The effectiveness of a glycol as a as a free radical quencher per unit of glycol, however, decreases with increasing concentration. Telechelic dihydroxy free radical quencher also includes glycol ethers. Exemplary glycols and glycol ethers are described in U.S. Pat. Nos. 4,040,863 and 5,336,425, the disclosures of which are expressly incorporated herein by reference.

In some embodiments, the compositions of the present invention are substantially free of, or even totally free of, telechelic dihydroxy free radical quenchers, as these organic molecules are volatile and can create health-safety issues.

In another embodiment, the free radical quencher is an alcohol, preferably an alcohol that is soluble in the diluent. Preferably, the alcohol is a secondary alcohol aromatic alcohols, e.g., BHT (3,5-di-tert-butyl-4-hydroxytoluene), tert-butyl-4-hydroxyanisole, resorcinol, and hydroquinone are preferred examples. Alcohols are inexpensive, readily removable from the surface of most substrates, and are typically freely soluble in the diluents used in the methods of the invention. Alcohols can economically be added in large amounts, e.g., greater than about 2% and, in many cases, greater than about 4% by weight, and this helps effectiveness. Any alcohol is useful so long as the alcohol is soluble in the diluent, which is typically water. Preferred alcohols are isopropanol and 2-butanol. Other useful alcohol free radical quenchers include cyclohexanol and methylcyclohexanol, in amounts described in U.S. Pat. No. 4,040,863, the disclosure of which is expressly incorporated herein by reference. The key is the quenching efficiency—if a molecule reacts with a free radical, and is itself then transformed into a free radical with sufficient stability that it can react with diluent and/or substrate, then the component will have a low quenching efficiency.

In some embodiments, the post chemical mechanical polishing cleaning compositions of the present invention are substantially free of, or even totally free of, alcohol free radical quenchers, since alcohols are volatile and can create health-safety issues. However, if alcohol free radical quenchers are used, it is preferred that they are used with one or more other classes of free radical quenchers.

In another embodiment, the free radical quencher is a ketone. Aliphatic ketones with secondary (alpha) hydrogens in conjugation with the 0 group are preferred-methyl-butyl ketone is not preferred, while methyl ethyl ketone is preferred. Ketones are inexpensive, readily removable from the surface of most substrates, and are typically freely soluble in the diluent used in the methods of the invention. Typically, ketones can economically be added in large quantities, e.g., greater than about 2% and, in many cases, greater than 4% by weight, and this helps effectiveness.

In some embodiments, the post chemical mechanical polishing cleaning compositions of the present invention are substantially free of, or even totally free of, ketone free radical quenchers, as these organic molecules are volatile and can create health-safety issues. If used, ketone free radical quenchers are advantageously used with one or more other classes of free radical quenchers.

In another embodiment, ascorbic acid is used as the free radical quencher. Ascorbic acid can be used alone or can be used with one or more other free radical quenchers. Ascorbic acid is readily soluble in the diluents used in the methods of the invention and is effective and inexpensive. Although ascorbic acid has a slight chelating effect, it is not classified herein as a chelator. Any amount up to about 15% of ascorbic acid can be used. In one embodiment, the amount of ascorbic acid ranges from about 0.05%. to about 4% In another embodiment, the amount of ascorbic acid ranges from about 0.2% to 2%. In another embodiment, the amount of ascorbic acid is about 0.5%. Ascorbic acid can be admixed with the oxidizer, if present, at the point of use or it can be mixed in tanks and stored, for example for as long as about three days. While ascorbic acid is most preferred, some or all of the ascorbic acid can be replaced with citric acid.

In another embodiment, the free radical quenchers is retinoic acid, or a salt thereof (“retinoic acid quenchers”) Without wishing to be bound by theory, it is believed that alternating double bonds in the alkyl tail of retinoic acid make retinoic acid quenchers a stable free radical quencher. While retinoic acid quenchers are not regenerable in an absolute sense, they do have numerous sites that can react with free radicals, so as used herein they are considered to be regenerable. The most effective use of retinoic acid quenchers is with point of use mixing. Any amount of retinoic acid quencher up to about 10% can be used. In one embodiment, the amount of retinoic acid quencher ranges from about 0.05% to about 4%. In another embodiment, the amount of retinoic acid quencher ranges from about 0.2% to about 2%. In another embodiment, the amount of retinoic acid quencher is about 0.5%. Retinoic acid quenchers can be admixed with the oxidizer at the point of use or can be mixed in tanks and stored, for example, for up to a day.

In some embodiments, the post chemical mechanical polishing cleaning compositions of the present invention are substantially free of, or even totally free of, retinoic acid quenchers, as these organic molecules are relatively expensive. If used, retinoic acid quenchers are advantageously used with one or more other free radical quenchers.

In another embodiment, the free-radial quenchers is D-alpha-tocopherol. These free radical quenchers are especially useful when an organic diluent is present in the post chemical mechanical polish cleaning composition. In aqueous compositions, these free radical quenchers can be used in low concentrations, e.g., at concentrations ranging from about 0.01% to about 0.2%. D-alpha-tocopherol and derivatives thereof are stable free radical quenchers. Although D-alpha-tocopherol and derivatives thereof are not regenerable in an absolute sense, they do have numerous sites that can react with a free radical, so as used herein they are considered to be regenerable.

In one embodiment, the compositions of the present invention are substantially free of, or even totally free of, D-alpha-tocopherol or a derivative thereof, as these organic molecules are relatively expensive.

In another embodiment, the free radical quencher is selected from thiamine, 2-propanol, an alkyl glycol, a 1,3 cyclo-alkene (e.g. cyclohexadiene compounds), an aromatic diazines (e.g. azobenzene compounds), phosphorous acid or an ester thereof, or an unsaturated amine.

Preferred free-radical-quenchers include ascorbic acid, retinoic acid, D-alpha-tocopherol, an inorganic acid, a silicate, a glycol, a metal ion, and solid cerium compounds. In one embodiment, the free radical quencher quenches is ascorbic acid. In one embodiment, the free radical quencher quenches is retinoic acid. In one embodiment, the free radical quencher quenches is D-alpha-tocopherol. In one embodiment, the free radical quencher quenches is an inorganic acid. In one embodiment, the free radical quencher quenches is a silicate. In one embodiment, the free radical quencher quenches is a glycol. In one embodiment, the free radical quencher quenches is a metal ion. In one embodiment, the free radical quencher quenches is a solid cerium compound.

As used herein the term “substantially quench free radicals” means that a free radical quencher(s) in a composition quenches a sufficient amount of free radicals in the composition to reduce corrosion of the most corrosion susceptible portion of the substrate, e.g., the metal components, to a rate with is less than 50%, preferably less than 25%, and more preferably less than 10%, of the corrosion that would exist without having the quencher(s) present.

In one embodiment, two or more free radical quenchers are used in the post chemical mechanical polish cleaning composition. Generally, the total amount of free radical quencher used is sufficient to substantially quench free radicals. Complete quenching, of free-radicals, is generally not economically feasible unless the quenchers used have other functions, for example as chelators. However, complete quenching of free radicals allows one to quantify the reduction in the amount of corrosion on the surface of a substrate in the presence of the free radical quencher. Inhibition is acceptable if the amount of corrosion of the surface of a substrate is reduced by an amount that is at least 50% less than, preferably at least 25% less than, and more preferably at least 10% less than, the amount of corrosion that would occur in the absence of the free radical quencher.

The concentrations of free radical quencher in the post chemical mechanical polishing composition will be apparent to those of skill in the art having benefit of this disclosure. The concentrations of free radical quencher in the post chemical mechanical polish cleaning composition is dependent on such factors as 1) the efficacy of the free radical quenchers selected, 2) the free radical generating capacity of the residue contacting the surface of the substrate after the polishing step, 3) the free radical generating capacity of any oxidizers in the post chemical mechanical polish cleaning composition, 4) the cost and other utility of the free radical quenching materials, and 5) the susceptibility of the surface of the substrate to being damaged by free radicals.

The amount of free radical quencher used in the post chemical mechanical polish cleaner compositions is typically the smallest amount that is effective to substantially quench free radicals. In one embodiment, the amount of the free radical quencher ranges from about 0.01% to about 5.0%. In another embodiment, the amount of the free radical quencher ranges from, about 0.05% to about 0.6%. In another embodiment, the amount of the free radical quencher ranges from about 0.7% to about 1.5%. In another embodiment, the amount of the free radical quencher ranges from about 1.5% to about 2.5%. In another embodiment, the amount of the free radical quencher ranges from about 2.5% and about 5% by weight of the compositions.

Preferred free radical quenchers are stable. Preferably, the free radical quencher does not quickly lose its ability to quench radicals in a composition when the free radical quencher is dissolved in the composition. A free radical quencher that loses half its ability to quench radicals in a composition in less than 20 minutes after being added to the composition (such as a chemical mechanical polishing composition or a post chemical mechanical polish cleaning composition) at a temperature of about 45° C. are not useful. While a free radical quencher that maintains half of its ability to quench radicals after it has been admixed into a composition for about eight hours can easily be used in industry, it is preferred that the free radical quencher maintain at least half of its ability to quench radicals after it has been admixed into a composition for about 3 days. This is done by merely using standard techniques to determine whether at least half of the quencher is still present after 3 days, as opposed to more elaborate techniques such as ESR spectroscopy. The stability of the free radical quencher in a composition is typically a function of both of the concentration of free radicals produced in the composition and of the concentration of the free radical quencher. A free radical quencher at a given concentration in a given solution is considered “stable” if at least half of its ability to quench radicals remains 3 days after the free radical quencher is added to a composition at temperature of about 45° C. A free radical quencher at a given concentration in a given solution is considered “quasi-stable” if at least half of its ability to quench radicals remains 12 hours after the free radical quencher is added to a composition at temperature of about 45° C. Generally, to be useful, a free radical quencher must maintain at least half of its ability to quench radicals after it has been admixed into a composition for at least about 10 minutes; such compositions, however, must be prepared by point of use mixing. Measurable changes on time scales shorter than that create too many uncertainties regarding concentration and activity to be used during typical processing operation.

While point of use mixing of unstable free radical quenchers is possible, a stable free radical quencher is advantageous since it can be added to a post chemical mechanical polishing composition well before use.

Another class of preferred free-radical-quenching-compounds are compounds that can react with a free radical and still maintain its function as a free radical quencher. We use the term “regenerable free radical quencher” to describe these compounds. The term “regenerable free radical quencher,” as used herein, means that the free radical quencher can react with more than one free radicals without losing its effectiveness as a free radical quencher. Regenerable compounds are typically stable or at least quasi-stable.

In a preferred embodiment, the post chemical mechanical polish cleaner composition comprises water as the diluent and from about 0.001% to about 10% of the free radical quencher.

In another embodiment, the post chemical mechanical polish cleaner composition comprises water as the diluent and from about 0.01% to 0.3% of the free radical quencher.

In another embodiment, the post chemical mechanical polish cleaner composition comprises water as the diluent and from about 0.31% to 0.7%, of the free radical quencher.

In another embodiment, the post chemical mechanical polish cleaner composition comprises water as the diluent and from about 0.7% to 2% of the free radical quencher.

In another embodiment, the post chemical mechanical polish cleaner composition comprises water as the diluent and from about 2% to 10% of the free radical quencher.

As noted above, in one embodiment, the post chemical mechanical polish cleaning composition further comprises an oxidizer. The oxidizer can be an oxidizer that does not generate free radicals or an oxidizer that does generate free radicals. In one embodiment, the oxidizer is an oxidizer that does generate free radicals. In one embodiment, the oxidizer is an oxidizer that does not generate free radicals.

Representative oxidizers that generate free radicals that are useful in the methods of the invention include, but are not limited to, peroxides; peroxydiphosphates; persulfates; periodic acid; and, to a lesser extent hydroxylamine, and salts thereof. Ozone is also an oxidizer that can form free radicals. Preferred oxidizers for use in the methods of the invention are hydrogen peroxide, ammonium persulfate, periodic acid, and hydroxylamine. Preferably, the oxidizer in the post chemical mechanical polish cleaning composition is present in an amount sufficient to remove absorbed contaminant ions and residual chemical mechanical polishing composition from the surface of the substrate in a commercially acceptable processing time.

In one embodiment, the oxidizer is present in an amount ranging from about 0.05% to about 0.5%. In another embodiment, the oxidizer is present in an amount ranging from about 0.5% to about 5%. Generally, increasing the amount of oxidizer decreases the processing time. Amounts up to about 20% are useful, but such amounts are generally not needed in a post chemical mechanical polish cleaning compositions, unless the oxidizer is weak, e.g., hydroxylamine.

The oxidizer, hydroxylamine can form free radicals in the presence of, for example, certain forms of iron or copper Derivatives of hydroxylamine, however, are much less prone to forming free radicals. Examples of derivatives of hydroxylamine according to the invention include, but are not limited to, N-methyl-hydroxylamine, N,N-dimethyl-hydroxylamine, N-ethyl-hydroxylamine, N,N-diethyl-hydroxylamine, methoxylamine, ethoxylamine, and N-methyl-methoxylamine. It should be understood that hydroxylamine and its derivatives, may also be used in the form of a salt, e.g., a sulfate salt, a nitrate salt, a phosphate salt, a chloride salt, or an acetate salt, and the invention includes these forms of hydroxylamine compounds and their derivatives as oxidizers. When hydroxylamine or a derivative of hydroxylamine is present as a salt, the theoretical flash point of hydroxylamine or the hydroxylamine derivative is advantageously increased. In one embodiment, the oxidizer is a salt of hydroxylamine or a derivative of hydroxylamine.

The amount of hydroxylamine, derivative of hydroxylamine, or salt thereof in the post chemical mechanical polish cleaning composition can range from about 0.01% to about 35%. In one embodiment, the amount of hydroxylamine, derivative of hydroxylamine, or salt thereof ranges from about 1% to about 25%. In another embodiment, the amount of hydroxylamine, derivative of hydroxylamine, or salt thereof ranges from about 5% to about 20%. In another embodiment, the amount of hydroxylamine, derivative of hydroxylamine, or salt thereof ranges from about 1% to about 10%. In another embodiment, the amount of hydroxylamine, derivative of hydroxylamine, or salt thereof ranges from about 10% to about 20%. In another embodiment, the amount of hydroxylamine, derivative of hydroxylamine, or salt thereof ranges from about 0.01% to about 1%. In another embodiment, the amount of hydroxylamine, derivative of hydroxylamine, or salt thereof ranges from about 0.1% to about 3%. In another embodiment, the amount of hydroxylamine, derivative of hydroxylamine, or salt thereof ranges from about 0.01% to about 0.2%.

Therefore, in some embodiments, the composition according to the invention are substantially free from hydroxylamine, a derivative of hydroxylamine, and salts thereof.

Particular combinations merit special discussion. In one embodiment of the method, the chemical mechanical polishing composition comprises an oxidizer that forms free radicals. Examples of oxidizers that form free-radicals, include, but are not limited to, peroxides, peroxydiphosphates, persulfates, and periodic acid.

The formation of free radical can be enhanced in some circumstances. For example, when an oxidizer is combined with dissolved or absorbed iron, copper, or silver, more free radicals are formed than would form without the dissolved or absorbed metal species. When these metals are coated to a solid, for example on an abrasive or on a dielectric portion of a substrate, free radical formation may be greatly increased. Additionally, some chelating compounds complex with iron, copper, or silver to create metal-ligand complexes that, in the presence of an oxidizer, lead to more free radical formation than would occur in the presence of the uncomplexed metal ion. Copper, that is removed from the surface of a substrate during polishing can complex with a chelator to form a complex that catalyzes the formation free radicals from oxidizers. For example, U.S. Pat. No. 6,242,351 states that a copper-glycine complex catalyzes the decomposition of hydrogen peroxide and promotes free radical formation. In some circumstances the presence of a metal can lead to the formation of free radicals from oxidizers. For example, hydroxylamine in the presence of copper can form NO. free radicals.

In a second embodiment of the method, the chemical-mechanical-polishing composition used to polish the surface of the substrate comprises an oxidizer that forms free radicals and one or more of a dissolved metal or a metal-coated abrasive material. In this case, the added metal may greatly promote free radical formation.

In a third embodiment, the post-chemical-mechanical-polish cleaning composition comprises an oxidizer that can form free radicals. In one embodiment, the free radicals are oxygen containing free radicals.

In a fourth embodiment, the post-chemical-mechanical-polishing cleaner composition comprises an oxidizer that does not form free radicals.

In a fifth embodiment, the conditions of the first and the third embodiments listed above are met, or the conditions of the second and the third embodiments listed above are met.

In each of these embodiments, the surface of the substrate that has been polished is contacted with the post-chemical mechanical polish cleaning composition for a period of time sufficient to clean the substrate of residual chemical mechanical polishing cleaner composition and contaminants such as contaminating metal ions that are absorbed on the surface of the substrate. A representative amount of contact time is from 2 seconds to one minute.

The above-described post chemical mechanical polishing cleaning method can be used after any chemical mechanical polishing method and using any chemical mechanical polishing composition known in the art. The method is especially useful when the chemical mechanical polishing composition comprises a metallic oxidizer (e.g., iron salts such as iron nitrate, with or without an additional oxidizer), a metal that promotes radical formation (e.g., iron coated on a particle), periodic acid, hydrogen peroxide, an organic peroxide, ozone, a peroxydisulfate, or a persulfate.

Generally, single wafer processing technology is preferred, as the transition time from polishing to cleaning is minimized. If single wafer processing is not available, it is preferred that the chemical mechanical polishing composition also comprise free radical quenchers for at least the end of the polishing process, such that residual chemical mechanical polishing compositions remaining on the wafer until cleaning have a sufficient quantity of free radical quenchers.

The post chemical mechanical polish cleaning composition can also contain other optional components such as a film former, a surfactant/rheological control agent, a viscosity enhancing agent, a coagulant, a pH adjusters, a pH regulators, a pH buffer, an anti-foaming agent, or a dispersing agent, all of which are well known to those of ordinary skill in the art.

In one embodiment, the post chemical mechanical polish cleaning composition further comprises a film former. Preferably, however, the post chemical mechanical polishing cleaning composition is free of film formers. Although, film formers slow corrosion, they can interfere with subsequent processing steps, therefore the presence of film formers is generally discouraged. When present, any suitable film-forming agent known to those skilled in the art can be used. Suitable film-forming agents include, but are not limited to, heterocyclic organic compounds, particularly nitrogen-containing heterocyclic compounds and salicylic acid. Suitable film-formers also include, benzotriazole, triazole, benzimidazole, and mixtures thereof, which can be added or removed from a substrate by changing the pH, as is known in the art. In many cases, these compounds are also used as free radical quenchers. When a compound is used as a film former it is present in an amount and under conditions such that the compound adheres to at least certain portions of the surface of the substrate. In contrast, when a compound is used as a free radical quencher, the compound is present in an amount that does not form a film on the surface of the substrate. In one embodiment, the film-former is present in an amount ranging from about 2% to about 10% by weight based on the weight of the composition.

In one embodiment, the post chemical mechanical polish cleaning composition further comprises a rheological control agent. Suitable rheological control agents useful in the methods of the invention include, but are not limited to, polymeric rheological control agents such as urethane polymers (e.g., urethane polymers with a molecular weight greater than about 100,000 Daltons) and polymers, copolymers, and oligomers of acrylates comprising one or more acrylic subunits (e.g., vinyl acrylates and styrene acrylates).

In one embodiment, the post chemical mechanical polish cleaning composition further comprises a surfactant. Suitable surfactants useful in the methods of the invention include, but are not limited to, cationic surfactants, anionic surfactants, anionic polyelectrolytes, nonionic surfactants, amphoteric surfactants, and fluorinated surfactants. Use of surfactant and/or rheological control agents are generally discouraged.

For the purposes of this disclosure, any free-radical quencher that falls under the definition of an optional components of the post chemical mechanical polish cleaning composition or the post etcher cleaner composition is specifically excluded from the group comprising that optional component.

The anti-corrosion effect produced by incorporating a free radical quencher in a post chemical mechanical polish cleaning composition useful in the methods of the invention is generally not pH dependent. In other words, the corrosion retarding phenomenon is observed throughout a broad range of pH.

The post chemical mechanical polishing cleaning composition used in the methods of the invention are prepared by dispersing the free radical quencher in the diluent. If an oxidizer is included in the post chemical mechanical polishing cleaning composition, the oxidizer can be dispersed, in the diluent either before or after the free radical quencher has been added. The post chemical mechanical polish cleaning composition can also be prepared in concentrated form as a concentrate. The concentrate then only needs to be diluted with water.

4.2. Methods of chemical mechanical polishing by adding a free radical quencher to the CMP composition at the end of the polishing step. In a second embodiment of the invention, one or more free radical quenchers is added to a chemical mechanical polishing composition that contacts the surface of a substrate as the polishing process is approaching the end-point where polishing is terminated, i.e., just prior to completing the chemical mechanical polishing step.

The method comprises the steps of:

A) providing a substrate comprising a surface;

B) polishing the surface of the substrate with a chemical-mechanical-polishing composition comprising
(i) an oxidizer; and
(ii) a diluent;
   wherein the chemical-mechanical-polishing composition contains free radicals; and

C) adding a free radical quencher to the chemical mechanical polishing composition just prior to completing polishing of the surface of the substrate with the chemical mechanical polishing composition, wherein the free radical quencher is added in an amount sufficient to reduce corrosion of the surface of the substrate to less than 50% of the amount of corrosion that would occur in the absence of the of the free radical quencher.

As discussed above, without wishing to be bound by theory, it is believed that corrosion of the surface of the substrate is caused by free radicals present in the chemical mechanical polishing composition when the surface is not being polished with the rotating pads.

Suitable diluents, for use in the chemical mechanical polishing composition include, but are not limited to water, C1 to C4 alcohols, and mixtures thereof. In one embodiment, the diluent is water, preferably deionized water.

As used herein, the phrase “just prior to completing polishing of the surface of the substrate” means the time point when only a small fraction of the polishing step remains, for example, when at least 80% of the time of the polishing step, i.e., the time that the surface of the substrate is in contact with a rotating polishing pad, has elapsed. In another embodiment, “just prior to completing polishing of the surface of the substrate” is when at least 90% of the time of the polishing step has elapsed. In another embodiment, “just prior to completing polishing of the surface of the substrate” is when at least 95% of the time of the polishing step has elapsed. In another embodiment, “just prior to completing polishing of the surface of the substrate” is when at least 99% of the time of the polishing step has elapsed.

Typically, the free radical quenchers are added to the chemical-mechanical-polishing composition when there is less than 1 minute before the polishing process is terminated. In another embodiment, the free radical quenchers are added to the chemical-mechanical-polishing composition when there is less than 30 seconds before the polishing process is terminated. In another embodiment, the free radical quenchers are added to the chemical-mechanical-polishing composition when there is less than 15 seconds before the polishing process is terminated. In another embodiment, the free radical quenchers are added to the chemical mechanical polishing composition when there is less than 10 seconds before the polishing process is terminated. In another embodiment, the free radical quenchers are added to the chemical-mechanical-polishing composition when there is less than 5 seconds before the polishing process is terminated.

Any chemical mechanical polishing composition known to those skilled in the art can be used in the methods of the invention. Representative chemical mechanical polishing compositions useful in the method of the invention include those described above in section 4.1.

Any oxidizer known to those skilled in the art can be used in the methods of the invention. Representative oxidizers and concentration of the oxidizers useful in the method of the invention include those described above in section 4.1.

Suitable free radical quenchers and concentrations of free radical quenchers useful in the methods of the invention include those described above in section 4.1.

Preferred free-radical-quenchers are ascorbic acid, retinoic acid, D-alpha-Tocopherol, inorganic-acid free-radical-quenchers, silicate free-radical-quenchers, glycols, metal-ion-containing free-radical-quenchers, and cerium oxides free-radical-quenchers.

If free radical quenchers are included in the chemical mechanical polishing composition during the entire polishing step, rather than being added at the end of the polishing process, as described in U.S. Pat. No. 6,508,953, then the desired activity of the free radicals during the polishing process is lost. As discussed above, free radicals present in the chemical mechanical polishing composition are desirable since they improve the rate of polishing. Free radicals, however, can also lead to corrosion of the surface of the substrate. By only adding the free radical quencher at the end of the polishing step, the benefits of free radicals during polishing are obtained but they are neutralized before polishing is completed and therefore do not remain on the surface of the substrate where they can corrode the surface of the substrate after the rotating polishing pad is removed. If the polishing equipment is designed for point of use mixing, simply adding the post chemical mechanical polish cleaning composition to the chemical mechanical polishing composition can provide a reduction in corrosion of the surface of the substrate.

Moreover, adding free radical quenchers to the chemical mechanical polishing composition at the end of the polishing process can result in a decrease in the rate at which material is removed from the surface of the substrate that advantageously results in a lower rate of contamination the surface of the substrate by residual material removed from the substrate by the polishing step. Indeed, addition of chelating-type free radical quenchers, rather than, for example, inorganic or non-chelating free radical quenchers, can further reduce contamination resulting from material removed from the substrate by polishing.

In the earlier-described embodiment, described above in section 4.1, wherein the surface of the substrate is contacted with a radical quencher that is included in a post chemical mechanical polish cleaning composition, the capacity of free radicals in any residue remaining on the surface of the substrate to cause corrosion is generally minimal. Accordingly, the free radical quencher can be added after polishing is completed. Under some circumstances, however, the capacity of free radicals in any residue remaining on the surface of the substrate to cause corrosion is significant such that even a short time between the chemical mechanical polishing step and the post chemical mechanical polish cleaning step is sufficient to cause corrosion of the surface of the substrate. In these circumstances, it is advantageous to add the free radical quencher to the chemical mechanical polishing composition just prior to completing polishing of the surface of the substrate. Similarly, in circumstances where the free radicals readily cause corrosion of the surface of the substrate or when there is a significant lag between the chemical mechanical polishing step and the post chemical-mechanical-polish cleaning step it is advantageous to add the free radical quencher to the chemical mechanical polishing composition just prior to completing polishing of the surface of the substrate.

For certain substrates, such as those containing copper with a tantalum barrier layer, two polishing steps are performed. The first polishing step uses a first chemical mechanical polishing composition to remove bulk copper and the second polishing step uses a second chemical mechanical polishing solution to remove the barrier layer. In such a process, the free radical quencher should be incorporated in the second chemical mechanical polishing composition, either continuously or at the conclusion of the second polishing step, while the first chemical mechanical polishing composition need not contain free radical quenchers.

The chemical mechanical polishing compositions used in the methods of the invention can further comprise one or more optional components such as those described above in section 4.1.

4.3. Methods of etching using a post-etching cleaner composition containing a free radical quencher. A third embodiment of the invention is directed to a method of post etch cleaning. The method involves the steps of providing a substrate having a surface that has been etched and, optionally, ashed, and contacting the surface of the etched substrate with a post-etch cleaner containing a free radical quencher.

The method comprises the steps of:

A) providing a substrate comprising a surface that has been etched with an etching composition,

B) contacting the etched substrate surface with a post-etch cleaner composition comprising:
(i) an oxidizer,
(ii) a diluent, and
(iii) a free radical quencher in an amount sufficient to reduce corrosion of the surface of the substrate to less than 50% of the amount of corrosion that would occur in the absence of the of the free radical quencher.

In one embodiment, the method further comprises the step of removing the post-etch cleaner composition from the substrate.

Without wishing to be bound by theory, it is believed that corrosion of the surface of the substrate is caused by free radicals present in the etching composition.

Suitable diluents, for use in the chemical mechanical polishing composition include, but are not limited to water, C1 to C4 alcohols, and mixtures thereof. In one embodiment, the diluent is water, preferably deionized water.

Any etching composition known to those skilled in the art can be used in the methods of the invention. Representative etching compositions useful in the method of the invention include, but are not limited to peroxide etchants, peracetic acic etchants, and fluoride etchants.

Any oxidizer known to those skilled in the art can be used in the methods of the invention. Representative oxidizers and the concentrations of the oxidizers useful in the method of the invention include those described above in section 4.1.

Suitable free radical quenchers and concentrations of the free radical quenchers useful in the methods of the invention include those described above in section 4.1.

Preferred free-radical-quenchers are ascorbic acid, retinoic acid, D-alpha-tocopherol, inorganic-acid free-radical-quenchers, silicate free-radical-quenchers, glycols, metal-ion-containing free-radical-quenchers, and cerium oxides free-radical-quenchers.

In a preferred embodiment, the post etch cleaner composition comprises water as the diluent and from about 0.001% to about 10% of the free radical quencher.

In another embodiment, the post etch cleaner composition comprises water as the diluent and from about 0.01% to 0.3% of the free radical quencher.

In another embodiment, the post etch cleaner composition comprises water as the diluent and from about 0.31% to 0.7%, of the free radical quencher.

In another embodiment, the post etch cleaner composition comprises water as the diluent and from about 0.7% to 2% of the free radical quencher.

In another embodiment, the post etch cleaner composition comprises water as the diluent and from about 2% to 10% of the free radical quencher.

Particular combinations merit special discussion. In a one embodiment, the etching composition comprises free-radicals. For example, the free radicals can be formed from the oxidizer. In this embodiment the amount of free radical quencher is preferably at least about 0.4% by weight since the etching composition may be difficult to remove from vias and lines formed by the etching process. Higher concentrations of the free radical quencher increases the amount of free radical quencher that comes in contact with these hard to reach areas. Examples of oxidizers useful in the etching compositions useful in the methods of the invention which generate free-radicals, include, but are not limited to, peroxides, peroxydiphosphates, peroxydisulfates, persulfates, and periodic acid.

In a second embodiment, the surface of the substrate is ashed prior to contacting the surface of the substrate with the post etch cleaner composition. In this embodiment, the amount of free radical quencher can be reduced to less than about 0.4% by weight since ashing converts metals, that can generate free radicals, to a species that is less likely to form free radicals. For example, ashing can converts a metal to a metal oxide or a metal fluoride.

In a third embodiment, the post-etch cleaner composition comprises an oxidizer and the substrate comprises one or more of copper, iron, or silver in a form that react with the oxidizer to generate free radicals. In this embodiment, it is preferred to have greater than about 0.2% or more by weight of free radical quencher included in the cleaner composition.

In a fourth embodiment, the post etch cleaning process is performed using single wafer processing technology. In this embodiment, cleaning times are typically reduced by using an etching composition that forms higher concentrations of free radicals. In this embodiment, the amount of free radical quenchers is beneficially greater than about 1%.

The post etch cleaning compositions used in the methods of the invention can further comprise one or more optional components such as those described in section 4.1.

The methods of the invention described in sections 4.1, 4.2, and 4.3 can be used in conjunction with any suitable substrate. In particular, the methods of the invention can be used in conjunction with memory or rigid disks, metals (e.g., noble metals), ILD layers, integrated circuits, semiconductor devices, semiconductor wafers, micro-electro-mechanical systems, ferroelectrics, magnetic heads, polymeric films, low and high dielectric constant films, and technical or optical glass. Suitable substrates include, but are not limited to, substrates comprising a metal, a metal oxide, or a metal composite. In one embodiment, the substrate comprises copper. In another embodiment, the substrate consist essentially of copper. In another embodiment, the substrate consists of copper. In another embodiment, the substrate comprises a copper composite or copper alloy. In another embodiment, the substrate consists essentially of a copper composite or copper alloy. In another embodiment, the substrate consists of a copper composite or copper alloy. In another embodiment, the substrate comprises a semiconductor base material. In another embodiment, the substrate consists essentially of a semiconductor base material. In another embodiment, the substrate consists of a semiconductor base material. Representative semiconductor base materials include single-crystal silicon, poly-crystalline silicon, amorphous silicon, silicon-on-insulator, and gallium arsenide. Glass substrates can also be used in conjunction with the present invention including technical glass, optical glass, and ceramics, of various types known in the art.

What is claimed is:

1. A method of cleaning the surface of a substrate after chemical mechanical polishing cleaning comprising:
A) providing a substrate comprising a surface that had been polished with a chemical mechanical polishing composition;
B) contacting the surface, for a time necessary to remove chemical mechanical polishing contaminants from the surface, with a post chemical mechanical-polish cleaning composition comprising:
(i) water, a C₁ to C₄ alcohol, or mixture thereof; and
(ii) a first free radical quencher selected from the group consisting of thiamine, 3,5-di-tert-butyl-4-hydroxytoluene, tert-butyl-4-hydroxyanisole, C₂ to C₄ alkyl hydroxy phenol, retinoic acid, D-alpha-tocopherol, a tin-containing compound, an iodide compound, cerium oxide particles having an average diameter ranging from about 2 nm to about 10 nm, or mixture thereof.

2. The method of claim 1, wherein in the free radical quencher comprises cerium oxide particles having an average diameter ranging from about 2 nm to about 10 nm.

3. The method of claim 1, wherein the free radical quencher comprises a tin-containing compound.

4. The method of claim 1, wherein the free radical quencher comprises an iodide compound.

5. The method of claim 1, wherein the free radical quencher comprises one or more of thiamine, 3,5-di-tert-butyl-4-hydroxytoluene, tert-butyl-4-hydroxyanisole, a C₂ to C₄ alkyl hydroxy phenol, retinoic acid, D-alpha-tocopherol, or mixture thereof.

6. The method of claim 5, wherein the post chemical mechanical-polish cleaning composition further comprises a second free radical quencher selected from ascorbic acid, a silicate, a C1-C4 alkyl glycol, resorcinol, hydroquinone, or mixture thereof.

7. The method of claim 5, wherein the post chemical mechanical-polish cleaning composition further comprises a carbonate.

8. The method of claim 1, wherein the free radical quencher comprises 3,5-di-tert-butyl-4-hydroxytoluene, tert-butyl-4-hydroxyanisole, or combination thereof.

9. The method of claim 1, wherein the free radical quencher comprises a C₂ to C₄ alkyl hydroxy phenol.

10. The method of claim 1 wherein the free radical quencher comprises retinoic acid, D-alpha-tocopherol, or mixture thereof.

11. The method of claim 1, wherein the free radical quencher is present in an amount sufficient to reduce corrosion of the surface of the substrate during said contacting to less than 50% of the amount of corrosion that would occur in the absence of the of the free radical quencher.

12. The method of claim 1, wherein the chemical-mechanical-polishing composition comprises a first oxidizer selected from the group consisting of a peroxide, a persulfate, and periodic acid, and further comprises at least one of a metal ion selected from iron, copper, or silver ions, where the metal ions promote formation of free radicals when contacting the first oxidizer.

13. A method of chemical mechanical polishing of a substrate comprising:
A) providing a substrate comprising a surface;
B) contacting and polishing the surface of the substrate for a period of time with a chemical-mechanical-polishing composition comprising an oxidizer selected from a peroxide, periodic acid, or a persulfate, wherein the chemical-mechanical-polishing composition contains free radicals; and
C) adding a free radical quencher to the chemical mechanical polishing composition contacting the surface of the substrate, wherein the free radical quencher is added after beginning the polishing period but prior to completing the polishing period of the surface of the substrate with the chemical mechanical polishing composition.

14. The method of claim 13, wherein the free radical quencher is added in an amount sufficient to reduce static corrosion of the surface of the substrate to less than 50% of the amount of corrosion that would occur in the absence of the of the free radical quencher.

15. The method of claim 13, wherein the polishing during the polishing period results in removal of a thickness of substrate material, wherein the free radical quencher is added to the chemical mechanical polishing composition after at least 80% of said thickness has been removed.

16. The method of claim 13, wherein the free radical quencher comprises thiamine, 3,5-di-tert-butyl-4-hydroxytoluene, tert-butyl-4-hydroxyanisole, retinoic acid, D-alpha-tocopherol, or any mixture thereof.

17. The method of claim 13, wherein the free radical quencher comprises C₁-C₄ alkyl glycols, a C₂ to C₄ alkyl hydroxy phenol, or any mixture thereof.

18. The method of claim 13, wherein the free radical quencher comprises cerium oxide particles having a diameter ranging from about 2 nm to about 10 nm.

19. The method of claim 13, wherein the free radical quencher comprises tin ions or a tin-containing compound.

20. The method of claim 13, wherein the free radical quencher comprises a carbonate compound, 2-propanol, resorcinol, an aromatic alcohol, hydroquinone, or any combination thereof.

21. The method of claim 13, wherein the free radical quencher comprises a silicate.

22. The method of claim 13, wherein the free radical quencher comprises ascorbic acid.

23. The method of claim 13, wherein the free radical quencher comprises phosphoric acid, phosphorous acid, sulfuric acid, sulfurous acid, or any combination thereof.

24. A method of cleaning the surface of a substrate after etching the surface of the substrate comprising:
A) providing a substrate comprising a surface that has been etched with an etching composition,
B) contacting the etched substrate surface with a post-etch cleaner composition comprising:
(i) an oxidizer selected from the group consisting of a persulfate, periodic acid, and a peroxide,
(ii) a diluent, and
(iii) a free radical quencher, wherein said free radical quencher comprises one or more selected from the group consisting of phosphoric acid, phosphorous acid, sulfuric acid, sulfurous acid, thiamine, an iodide compound, 2-propanol, aromatic alcohols, C₁-C₄ alkyl glycols, retinoic acid, D-alpha-tocopherol, ascorbic acid, a silicate, or any combination thereof.
